(19) United States
(12) Patent Application Publication
(10) Pub. No.: US 2010/0254758 A1
(43) Pub. Date: Oct. 7, 2010

(54) APPARATUS AND METHOD FOR FORMING A MECHANICAL, FLUID-TIGHT CONNECTION

(75) Inventors: Levi A. CAMPBELL, Poughkeepsie, NY (US); Michael J. ELLSWORTH, JR., Lagrangeville, NY (US); Prabjit SINGH, New Paltz, NY (US); Rebecca N. WAGNER, Torrance, CA (US)

Correspondence Address: HESLIN ROTHENBERG FARLEY & MESITI P.C., 5 COLUMBIA CIRCLE, ALBANY, NY, 12203, US

(73) Assignee: INTERNATIONAL BUSINESS MACHINES CORPORATION, Armonk, NY (US)

(21) Appl. No.: 12/418,950

(22) Filed: Apr. 6, 2009

(51) Int. Cl. F16L 33/207; H05K 7/20

(52) U.S. Cl. 403/409.1; 403/281; 361/689

(57) ABSTRACT

Apparatus and method are provided for forming a mechanical, fluid-tight connection. The apparatus includes a grooved fitting, which has an outer diameter sized to allow the fitting to reside within a tubing between which the fluid-tight connection is to be formed, and which includes a circumferential groove about an outer surface and one or more raised features within the circumferential groove. The apparatus also includes a ring formed of a shape memory alloy, which is transversely heat-shrinkable. The ring is sized to allow the ring to reside over the tubing. When the grooved fitting resides within the tubing and the ring is positioned over the tubing aligned over the circumferential groove in the grooved fitting, heat-shrinking of the ring results in deformation of the tubing into the circumferential groove and into contact with the raised feature(s) within the circumferential groove, thereby forming the mechanical, fluid-tight connection.

### TECHNICAL FIELD

The present invention relates in general to apparatuses and methods for forming a mechanical, fluid-tight connection for, for example, facilitating cooling of a computing system, such as a rack-mounted assemblage of individual computer server units.

### BACKGROUND OF THE INVENTION

The power dissipation of integrated circuit chips, and the modules containing the chips, continues to increase in order to achieve increases in processor performance. This trend poses a cooling challenge at both the module and system level. Increased air flow rates are needed to effectively cool high power modules and to limit the temperature of the air that is exhausted into the computer center.

In many large server applications, processors along with their associated electronics (e.g., memory, disk drives, power supplies, etc.) are packaged in removable drawer configurations stacked within a rack or frame. In other cases, the electronics may be in fixed locations within the rack or frame. Typically, the components are cooled by air moving in parallel air flow paths, usually front-to-back, impelled by one or more air moving devices (e.g., fans or blowers). In some cases it may be possible to handle increased power dissipation within a single drawer by providing greater air flow, through the use of a more powerful air moving device or by increasing the rotational speed (i.e., RPMs) of an existing air moving device. However, this approach is becoming problematic.

The sensible heat load carried by the air exiting the rack is stressing the ability of the room air conditioning to effectively handle the load. This is especially true for large installations with “server farms” or large banks of computer racks close together. In such installations not only will the room air conditioning be challenged, but the situation may also result in recirculation problems with some fraction of the “hot” air exiting one rack unit being drawn into the air inlet of the same rack or a nearby rack. This re-circulating flow is often extremely complex in nature, and can lead to significantly higher rack inlet temperatures than expected. In such installations, liquid cooling (e.g., water cooling) is an attractive technology to assist in managing the higher heat fluxes. The liquid absorbs the heat dissipated by the components/modules in an efficient manner, and the heat can be ultimately transferred from the liquid to an outside environment, whether air or other liquid coolant.

To introduce liquid cooling into one or more computer server units, it is necessary that the tubings and fittings meet existing specifications for flammability, as well as be acceptable in the limited volume environment of a typical electronics rack, such as a server cabinet.

### SUMMARY OF THE INVENTION

The shortcomings of the prior art are overcome and additional advantages are provided through the provision, in one aspect, of an apparatus for forming a mechanical, fluid-tight connection. The apparatus includes a grooved fitting and a ring. The grooved fitting has an outer diameter which allows a portion of the grooved fitting to reside within a tubing between which the mechanical, fluid-tight connection is to be formed. The grooved fitting includes a circumferential groove about an outer surface of the fitting and at least one raised feature within the circumferential groove. The circumferential groove is disposed in the portion of the grooved fitting which is to reside within the tubing. The ring is formed of a shape memory alloy, which is transversely heat shrinkable and has an axially-facing surface. An inner diameter of the ring, at the axially-facing surface, is sized to allow the ring to reside over the tubing. When the portion of the grooved fitting resides within the tubing and the ring resides over the tubing at least partially aligned over the circumferential groove in the outer surface of the groove fitting, heat shrinking of the ring results in deformation of the tubing into the circumferential groove and into contact with the at least one raised feature within the circumferential groove, thereby forming the mechanical, fluid-tight connection.

In another aspect, an assembly is provided for facilitating cooling of an electronic system. The assembly includes a deformable tubing and a mechanical, fluid-tight connection at one end of the deformable tubing. The deformable tubing is configured for carrying coolant towards or away from at least one heat generating component of the electronic system to be cooled. The mechanical, fluid-tight connection is formed between a grooved fitting of the assembly and the deformable tubing. The grooved fitting has an outer diameter sized so that at least a portion of the grooved fitting resides within the deformable tubing, and includes a circumferential groove about an outer surface thereof and at least one raised feature within the circumferential groove. The groove is disposed in the portion of the grooved fitting residing within the deformable tubing. The mechanical, fluid-tight connection further includes a ring formed of shaped memory alloy, which is transversely heat shrunk and has an axially-facing surface. An inner diameter of the ring, at the axially-facing surface, was sized to allow the ring to reside over the deformable tubing prior to the heat shrinking of the ring, wherein the heat shrinking of the ring produced deformation of the deformable tubing into the circumferential groove and into contact within the at least one raised feature of the circumferential groove, thereby defining the mechanical, fluid-tight connection at the at least one end of the deformable tubing of the cooling assembly.

In a further aspect, a method of forming a mechanical, fluid-tight connection is provided. The method includes obtaining a grooved fitting having an outer diameter sized to allow at least a portion of the grooved fitting to reside within a tubing between which the mechanical, fluid-tight connection is to be formed, the grooved fitting comprising a circumferential groove about an outer surface thereof and at least one raised feature within the circumferential groove, the circumferential groove being disposed in the at least a portion of the grooved fitting sized to reside within the tubing; obtaining a ring formed from a shape memory alloy, which is transversely heat-shrinkable and has an axially-facing surface, and wherein an inner diameter of the ring, at the axially-facing surface, is sized to allow the ring to reside over the tubing; placing the at least a portion of the grooved fitting within the tubing and positioning the ring over the tubing at least partially in alignment over the circumferential groove in the outer surface of the grooved fitting; and heat-shrinking the ring to deform the tubing into the at least one circumferential groove in the grooved fitting and into contact with the at least one raised feature within the circumferential groove, thereby forming the mechanical, fluid-tight connection.

Further, additional features and advantages are realized through the techniques of the present invention. Other embodiments and aspects of the invention are described in detail herein and are considered a part of the claimed invention.

### BRIEF DESCRIPTION OF THE DRAWINGS

The subject matter which is regarded as the invention is particularly pointed out and distinctly claimed in the claims at the conclusion of the specification. The foregoing and other objects, features, and advantages of the invention are apparent from the following detailed description taken in conjunction with the accompanying drawings in which:

FIG. 1 depicts one embodiment of a conventional raised floor layout of an air-cooled data center;

FIG. 2 depicts recirculation airflow patterns to be addressed in one implementation of a liquid cooling system, in accordance with an aspect of the present invention;

FIG. 3 depicts one embodiment of a coolant distribution unit for liquid cooling of one or more electronics racks of a data center, in accordance with an aspect of the present invention;

FIG. 4 is a plan view of one embodiment of an electronics subsystem layout illustrating an air and liquid cooling subsystem for hybrid cooling of components of the electronics subsystem, in accordance with an aspect of the present invention;

FIG. 5 depicts one detailed embodiment of a partially-assembled electronics subsystem layout, wherein the electronics subsystem includes eight heat-generating electronics components to be actively cooled, each having a respective liquid-cooled cold plate of a liquid-based cooling system coupled thereto, in accordance with an aspect of the present invention;

FIG. 6 is a cross-sectional elevational view of a conventional hose-barb connection between a fitting and tube;

FIG. 7 is a cross-sectional elevational view of an apparatus which forms a mechanical, fluid-tight connection, in accordance with an aspect of the present invention;

FIG. 8 is a cross-sectional elevational view of a more detailed embodiment of an apparatus such as depicted in FIG. 7, which forms a mechanical, fluid-tight connection, in accordance with an aspect of the present invention;

FIG. 9 is a cross-sectional elevational view of an alternate embodiment of an apparatus which forms a mechanical, fluid-tight connection, in accordance with an aspect of the present invention;

FIG. 10 is a cross-sectional elevational view of a more detailed embodiment of an apparatus such as depicted in FIG. 9, which forms a mechanical, fluid-tight connection, in accordance with an aspect of the present invention;

FIG. 11A is an isometric view of one embodiment of an apparatus for forming a mechanical, fluid-tight connection, in accordance with an aspect of the present invention;

FIG. 11B is a cross-sectional elevational view of the assembled apparatus of FIG. 11A, illustrating a mechanical, fluid-tight connection, in accordance with an aspect of the present invention;

FIG. 12A is an isometric view of an alternate embodiment of an apparatus for forming a mechanical, fluid-tight connection, in accordance with an aspect of the present invention;

FIG. 12B is a cross-sectional elevational view of the assembled apparatus of FIG. 12A, illustrating a mechanical, fluid-tight connection, in accordance with an aspect of the present invention; and

FIG. 12C is an isometric view of one embodiment of the retaining clip of the apparatus of FIGS. 12A & 12B, which facilitates forming a mechanical, fluid-tight connection, in accordance with an aspect of the present invention.

### DETAILED DESCRIPTION OF THE INVENTION

Generally stated, provided herein are a novel apparatus and method for forming a mechanical, fluid-tight connection for, for example, facilitating liquid cooling of one or more electronic subsystems within an electronics rack. The mechanical, fluid-tight connection is formed between a grooved fitting and a deformable tubing using a ring formed of a shaped memory alloy. The grooved fitting includes a circumferential groove about an outer surface thereof with one or more raised features within the circumferential groove. Upon positioning of the grooved fitting within the tubing and the ring over the tubing in at least partial alignment over the circumferential groove in the grooved fitting, heat shrinking of the ring results in deformation of the tubing into the circumferential groove and into contact with the raised feature(s) within the groove, thereby forming the mechanical, fluid-tight connection.

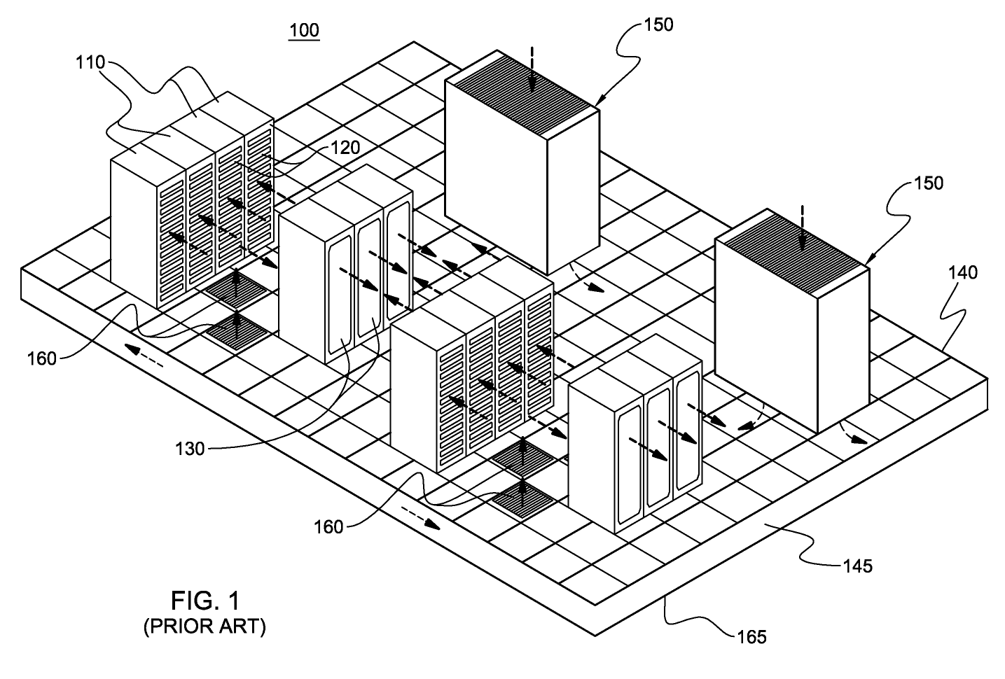

Before describing the apparatus and method further, a liquid cooling system is described below with reference to FIGS. 1-5. This system, which facilitates cooling one or more electronics racks within a data center, may be used in combination with which the apparatus and method presented herein. Note that FIGS. 1-5 are presented by way of example only, and that the apparatus and method for forming a mechanical, fluid-tight connection presented herein may be employed in a number of different applications. For example, reference for a further implementation co-filed, commonly assigned U.S. patent application Ser. No. ______, entitled “High Performance Dual-In-Line Memory (DIMM) Array Liquid Cooling Assembly and Method,” (Attorney Docket: IBM-POU920080191US1), the entirety of which is hereby incorporated herein by reference.

As used herein, the terms “electronics rack”, “rack-mounted electronic equipment”, and “rack unit” are used interchangeably, and unless otherwise specified include any housing, frame, rack, compartment, blade server system, etc., having one or more heat generating components of a computer system or electronics system, and may be, for example, a stand alone computer processor having high, mid or low end processing capability. In one embodiment, an electronics rack may comprise multiple electronics systems or subsystems, each having one or more heat generating components disposed therein requiring cooling. “Electronics system” or “electronics subsystem” refers to any sub-housing, blade, book, drawer, node, compartment, etc., having one or more heat generating electronic components disposed therein. Each electronics system or subsystem of an electronics rack may be movable or fixed relative to the electronics rack, with the rack-mounted electronics drawers of a multi-drawer rack unit and blades of a blade center system being two examples of subsystems of an electronics rack to be cooled.

“Electronic component” refers to any heat generating electronic component of, for example, a computer system or other electronics unit requiring cooling. By way of example, an electronic component may comprise one or more integrated circuit dies and/or other electronic devices to be cooled, including one or more processor dies, memory dies and memory support dies. As a further example, the electronic component may comprise one or more bare dies or one or more packaged dies disposed on a common carrier. As used herein, “primary heat generating component” refers to a primary heat generating electronic component within an electronics subsystem, while “secondary heat generating component” refers to an electronic component of the electronics subsystem generating less heat than the primary heat generating component to be cooled. “Primary heat generating die” refers, for example, to a primary heat generating die or chip within a heat generating electronic component comprising primary and secondary heat generating dies (with a processor die being one example). “Secondary heat generating die” refers to a die of a multi-die electronic component generating less heat than the primary heat generating die thereof (with memory dies and memory support dies being examples of secondary dies to be cooled). As one example, a heat generating electronic component could comprise multiple primary heat generating bare dies and multiple secondary heat generating dies on a common carrier. Further, unless otherwise specified herein, the term “liquid-cooled cold plate” refers to any conventional thermally conductive structure having a plurality of channels or passageways formed therein for flowing of liquid coolant therethrough. In addition, “metallurgically bonded” refers generally herein to two components being welded, brazed or soldered together by any means.

As used herein, “air-to-liquid heat exchanger” means any heat exchange mechanism characterized as described herein through which liquid coolant can circulate and which transfers heat between air and the circulating liquid; and includes, one or more discrete air-to-liquid heat exchangers coupled either in series or in parallel. An air-to-liquid heat exchanger may comprise, for example, one or more coolant flow paths, formed of thermally conductive tubing (such as copper or other tubing) in thermal communication with a plurality of air-cooled cooling fins. Size, configuration and construction of the air-to-liquid heat exchanger can vary without departing from the scope of the invention disclosed herein. A “liquid-to-liquid heat exchanger” may comprise, for example, two or more coolant flow paths, formed of thermally conductive tubing (such as copper or other tubing) in thermal communication with each other. Size, configuration and construction of the liquid-to-liquid heat exchanger can vary without departing from the scope of the invention disclosed herein. Further, “data center” refers to a computer installation containing one or more electronics racks to be cooled. As a specific example, a data center may include one or more rows of rack-mounted computing units, such as server units.

One example of facility coolant and system coolant is water. However, the concepts disclosed herein are readily adapted to use with other types of coolant on the facility side and/or on the system side. For example, one or more of the coolants may comprise a brine, a fluorocarbon liquid, a liquid metal, or other similar coolant, or refrigerant. In another example described herein, the facility coolant is a refrigerant, while the system coolant is water. All of these variations are possible, while still maintaining the advantages and unique features of the present invention.

Reference is made below to the drawings, which are not drawn to scale for reasons of understanding, wherein the same reference numbers used throughout different figures designate the same or similar components.

FIG. 1 depicts a raised floor layout of an air cooled data center 100 typical in the prior art, wherein multiple electronics racks 110 are disposed in one or more rows. A data center such as depicted in FIG. 1 may house several hundred, or even several thousand microprocessors. In the arrangement illustrated, chilled air enters the computer room via perforated floor tiles 160 from a supply air plenum 145 defined between the raised floor 140 and a base or sub-floor 165 of the room. Cooled air is taken in through louvered covers at air inlet sides 120 of the electronics racks and expelled through the back (i.e., air outlet sides 130) of the electronics racks. Each electronics rack 110 may have one or more air moving devices (e.g., fans or blowers) to provide forced inlet-to-outlet airflow to cool the electronic components within the drawer(s) of the rack. The supply air plenum 145 provides conditioned and cooled air to the air-inlet sides of the electronics racks via perforated floor tiles 160 disposed in a “cold” aisle of the computer installation. The conditioned and cooled air is supplied to plenum 145 by one or more air conditioning units 150, also disposed within the data center 100. Room air is taken into each air conditioning unit 150 near an upper portion thereof. This room air comprises in part exhausted air from the “hot” aisles of the computer installation defined by opposing air outlet sides 130 of the electronics racks 110.

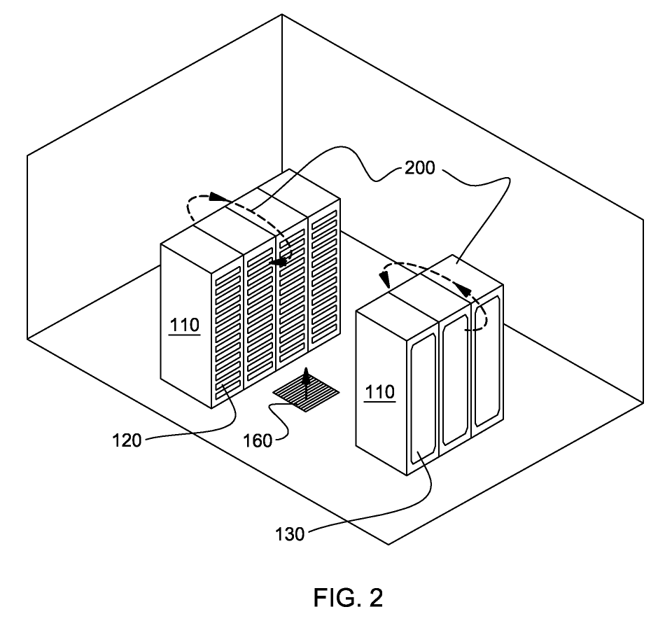

Due to the ever increasing airflow requirements through electronics racks, and limits of air distribution within the typical data center installation, recirculation problems within the room may occur. This is shown in FIG. 2 for a raised floor layout, wherein hot air recirculation 200 occurs from the air outlet sides 130 of the electronics racks 110 back to the cold air aisle defined by the opposing air inlet sides 120 of the electronics rack. This recirculation can occur because the conditioned air supplied through tiles 160 is typically only a fraction of the airflow rate forced through the electronics racks by the air moving devices disposed therein. This can be due, for example, to limitations on the tile sizes (or diffuser flow rates). The remaining fraction of the supply of inlet side air is often made up by ambient room air through recirculation 200. This recirculating flow is often very complex in nature, and can lead to significantly higher rack unit inlet temperatures than desired.

The recirculation of hot exhaust air from the hot aisle of the computer room installation to the cold aisle can be detrimental to the performance and reliability of the computer system(s) or electronic system(s) within the racks. Data center equipment is typically designed to operate with rack air inlet temperatures in the 18-35° C. range. For a raised floor layout such as depicted in FIG. 1, however, temperatures can range from 15-20° C. at the lower portion of the rack, close to the cooled air input floor vents, to as much as 45-50° C. at the upper portion of the electronics rack, where the hot air can form a self-sustaining recirculation loop. Since the allowable rack heat load is limited by the rack inlet air temperature at the “hot” part, this temperature distribution correlates to an inefficient utilization of available chilled air. Also, computer installation equipment almost always represents a high capital investment to the customer. Thus, it is of significant importance, from a product reliability and performance view point, and from a customer satisfaction and business perspective, to limit the temperature of the inlet air to the rack unit to be substantially uniform. The efficient cooling of such computer and electronic systems, and the amelioration of localized hot air inlet temperatures to one or more rack units due to recirculation of air currents, are addressed by the apparatuses and methods disclosed herein, as is reducing acoustic noise within the data center (e.g., by requiring less cooled air within the data center and less cooled airflow through the electronics racks to remove a given heat load, thereby reducing air-moving device requirements and hence acoustic noise within the data center).

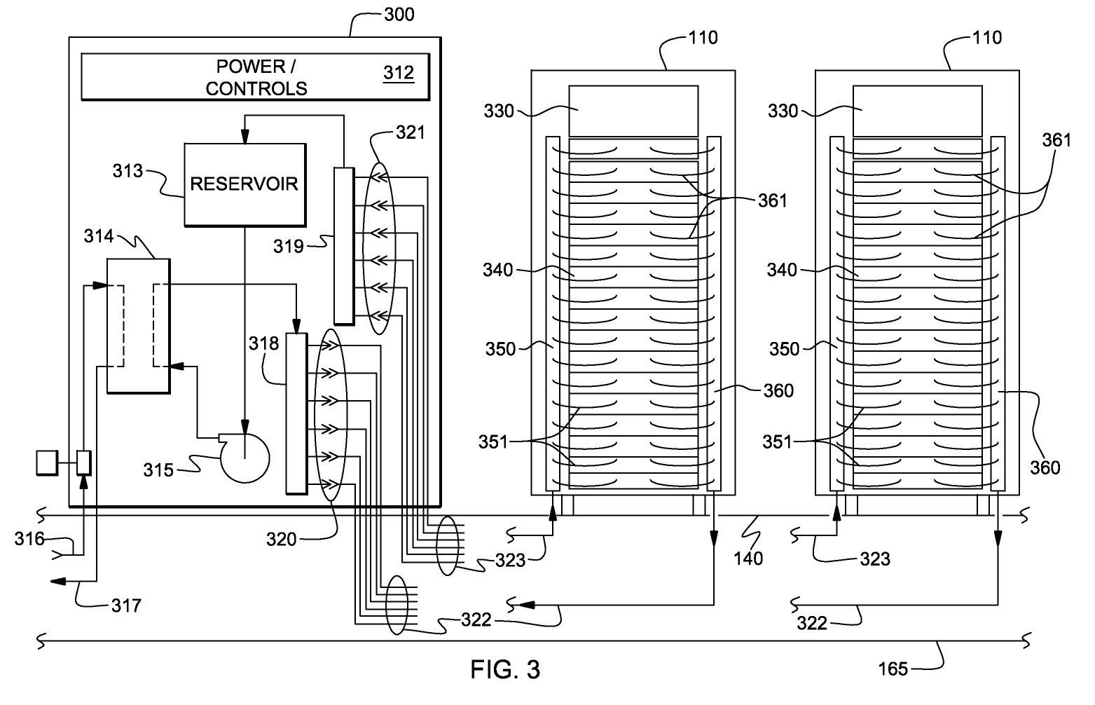

FIG. 3 depicts one embodiment of a coolant distribution unit 300 for a data center. The coolant distribution unit is conventionally a large unit which occupies what would be considered a full electronics frame. Within coolant distribution unit 300 is a power/control element 312, a reservoir/expansion tank 313, a heat exchanger 314, a pump 315 (often accompanied by a redundant second pump), facility water inlet 316 and outlet 317 supply pipes, a supply manifold 318 supplying water or system coolant to the electronics racks 110 via couplings 320 and lines 322, and a return manifold 319 receiving water from the electronics racks 110, via lines 323 and couplings 321. Each electronics rack includes (in one example) a power/control unit 330 for the electronics rack, multiple electronics subsystems 340, a system coolant supply manifold 350, and a system coolant return manifold 360. As shown, each electronics rack 110 is disposed on raised floor 140 of the data center and lines 323 providing system coolant to system coolant supply manifolds 350 and lines 322 facilitating return of system coolant from system coolant return manifolds 360 are disposed in the supply air plenum beneath the raised floor.

In the embodiment illustrated, the system coolant supply manifold 350 provides system coolant to the cooling systems of the electronics subsystems (more particularly, to liquid-cooled cold plates thereof) via flexible hose connections 351, which are disposed between the supply manifold and the respective electronics subsystems within the rack. Similarly, system coolant return manifold 360 is coupled to the electronics subsystems via flexible hose connections 361. Quick connect couplings may be employed at the interface between flexible hoses 351, 361 and the individual electronics subsystems. By way of example, these quick connect couplings may comprise various types of commercially available couplings, such as those available from Colder Products Company, of St. Paul, Minn., USA, or Parker Hannifin, of Cleveland, Ohio, USA.

Although not shown, electronics rack 110 may also include an air-to-liquid heat exchanger disposed at an air outlet side thereof, which also receives system coolant from the system coolant supply manifold 350 and returns system coolant to the system coolant return manifold 360.

FIG. 4 depicts one embodiment of an electronics subsystem 340 component layout wherein one or more air moving devices 411 provide forced air flow 415 to cool multiple components 412 within electronics subsystem 340. Cool air is taken in through a front 431 and exhausted out a back 433 of the drawer. The multiple components to be cooled include multiple processor modules to which liquid-cooled cold plates 420 (of a liquid-based cooling system) are coupled, as well as multiple arrays of memory modules 430 (e.g., dual in-line memory modules (DIMMs)) and multiple rows of memory support modules 432 (e.g., DIMM control modules) to which air-cooled heat sinks are coupled. In the embodiment illustrated, memory modules 430 and the memory support modules 432 are partially arrayed near front 431 of electronics subsystem 340, and partially arrayed near back 433 of electronics subsystem 340. Also, in the embodiment of FIG. 4, memory modules 430 and the memory support modules 432 are cooled by air flow 415 across the electronics subsystem.

The illustrated liquid-based cooling system further includes multiple coolant-carrying tubes connected to and in fluid communication with liquid-cooled cold plates 420. The coolant-carrying tubes comprise sets of coolant-carrying tubes, with each set including (for example) a coolant supply tube 440, a bridge tube 441 and a coolant return tube 442. In this example, each set of tubes provides liquid coolant to a series-connected pair of cold plates 420 (coupled to a pair of processor modules). Coolant flows into a first cold plate of each pair via the coolant supply tube 440 and from the first cold plate to a second cold plate of the pair via bridge tube or line 441, which may or may not be thermally conductive. From the second cold plate of the pair, coolant is returned through the respective coolant return tube 442.

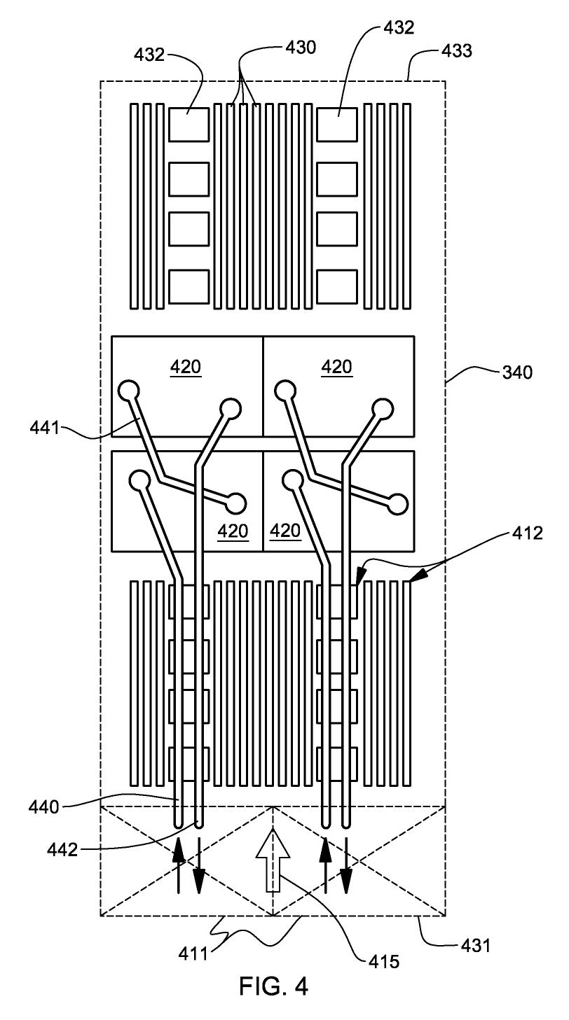

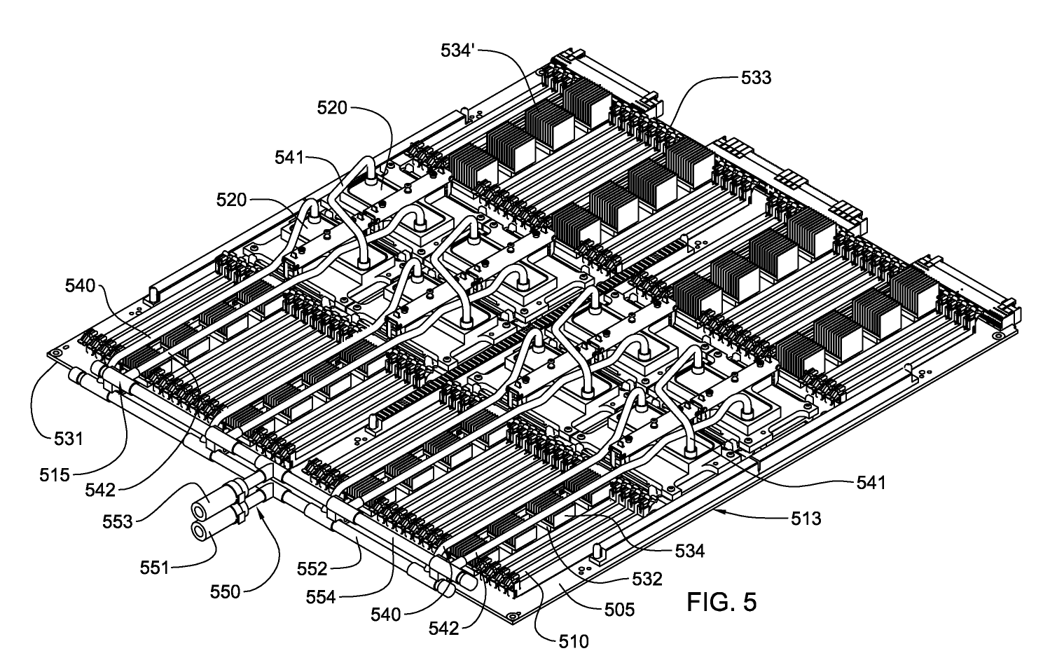

FIG. 5 depicts in greater detail an alternate electronics drawer layout comprising eight processor modules, each having a respective liquid-cooled cold plate of a liquid-based cooling system coupled thereto. The liquid-based cooling system is shown to further include associated coolant-carrying tubes for facilitating passage of liquid coolant through the liquid-cooled cold plates and a header subassembly to facilitate distribution of liquid coolant to and return of liquid coolant from the liquid-cooled cold plates. By way of specific example, the liquid coolant passing through the liquid-based cooling subsystem is chilled water.

As noted, various liquid coolants significantly outperform air in the task of removing heat from heat generating electronic components of an electronics system, and thereby more effectively maintain the components at a desirable temperature for enhanced reliability and peak performance. As liquid-based cooling systems are designed and deployed, it is advantageous to architect systems which maximize reliability and minimize the potential for leaks while meeting all other mechanical, electrical and chemical requirements of a given electronics system implementation. These more robust cooling systems have unique problems in their assembly and implementation. For example, one assembly solution is to utilize multiple fittings within the electronics system, and use flexible plastic or rubber tubing to connect headers, cold plates, pumps and other components. However, such a solution may not meet a given customer's specifications and need for reliability.

Thus, presented herein in one aspect is a robust and reliable liquid-based cooling system specially preconfigured and prefabricated as a monolithic structure for positioning within a particular electronics drawer.

FIG. 5 is an isometric view of one embodiment of an electronics drawer and monolithic cooling system, in accordance with an aspect of the present invention. The depicted planar server assembly includes a multi-layer printed circuit board to which memory DIMM sockets and various electronic components to be cooled are attached both physically and electrically. In the cooling system depicted, a supply header is provided to distribute liquid coolant from a single inlet to multiple parallel coolant flow paths and a return header collects exhausted coolant from the multiple parallel coolant flow paths into a single outlet. Each parallel coolant flow path includes one or more cold plates in series flow arrangement to cool one or more electronic components to which the cold plates are mechanically and thermally coupled. The number of parallel paths and the number of series-connected liquid-cooled cold plates depends, for example on the desired device temperature, available coolant temperature and coolant flow rate, and the total heat load being dissipated from each electronic component.

More particularly, FIG. 5 depicts a partially assembled electronics system 513 and an assembled liquid-based cooling system 515 coupled to primary heat generating components (e.g., including processor dies) to be cooled. In this embodiment, the electronics system is configured for (or as) an electronics drawer of an electronics rack, and includes, by way of example, a support substrate or planar board 505, a plurality of memory module sockets 510 (with the memory modules (e.g., dual in-line memory modules) not shown), multiple rows of memory support modules 532 (each having coupled thereto an air-cooled heat sink 534), and multiple processor modules (not shown) disposed below the liquid-cooled cold plates 520 of the liquid-based cooling system 515.

In addition to liquid-cooled cold plates 520, liquid-based cooling system 515 includes multiple coolant-carrying tubes, including coolant supply tubes 540 and coolant return tubes 542 in fluid communication with respective liquid-cooled cold plates 520. The coolant-carrying tubes 540, 542 are also connected to a header (or manifold) subassembly 550 which facilitates distribution of liquid coolant to the coolant supply tubes 540 and return of liquid coolant from the coolant return tubes 542. In this embodiment, the air-cooled heat sinks 534 coupled to memory support modules 532 closer to front 531 of electronics drawer 513 are shorter in height than the air-cooled heat sinks 534′ coupled to memory support modules 532 near back 533 of electronics drawer 513. This size difference is to accommodate the coolant-carrying tubes 540, 542 since, in this embodiment, the header subassembly 550 is at the front 531 of the electronics drawer and the multiple liquid-cooled cold plates 520 are in the middle of the drawer.

Liquid-based cooling system 515 comprises a preconfigured monolithic structure which includes multiple (pre-assembled) liquid-cooled cold plates 520 configured and disposed in spaced relation to engage respective heat generating electronic components. Each liquid-cooled cold plate 520 includes, in this embodiment, a liquid coolant inlet and a liquid coolant outlet, as well as an attachment subassembly (i.e., a cold plate/load arm assembly). Each attachment subassembly is employed to couple its respective liquid-cooled cold plate 520 to the associated electronic component to form the cold plate and electronic component assemblies. Alignment openings (i.e., thru-holes) are provided on the sides of the cold plate to receive alignment pins or positioning dowels during the assembly process, and connectors (or guide pins) are included within attachment subassembly which facilitate use of the attachment assembly.

As shown in FIG. 5, header subassembly 550 includes two liquid manifolds, i.e., a coolant supply header 552 and a coolant return header 554, which in one embodiment, are coupled together via supporting brackets. In the monolithic cooling structure of FIG. 5, the coolant supply header 552 is metallurgically bonded in fluid communication to each coolant supply tube 540, while the coolant return header 554 is metallurgically bonded in fluid communication to each coolant return tube 552. A single coolant inlet 551 and a single coolant outlet 553 extend from the header subassembly for coupling to the electronics rack's coolant supply and return manifolds (not shown).

FIG. 5 also depicts one embodiment of the preconfigured, coolant-carrying tubes. In addition to coolant supply tubes 540 and coolant return tubes 542, bridge tubes or lines 541 are provided for coupling, for example, a liquid coolant outlet of one liquid-cooled cold plate to the liquid coolant inlet of another liquid-cooled cold plate to connect in series fluid flow the cold plates, with the pair of cold plates receiving and returning liquid coolant via a respective set of coolant supply and return tubes. In one embodiment, the coolant supply tubes 540, bridge tubes 541 and coolant return tubes 542 are each preconfigured, semi-rigid tubes formed of a thermally conductive material, such as copper or aluminum, and the tubes are respectively brazed, soldered or welded in a fluid-tight manner to the header subassembly and/or the liquid-cooled cold plates. The tubes are preconfigured in the embodiment of FIG. 5 for a particular electronics system to facilitate installation of the monolithic structure in engaging relation with the electronics system.

Depending on the application, these preconfigured, metal tubes may be disadvantageous. For example, the above described coolant carrying tubes fabricated (for example), of metal lack mechanical compliance and are expensive to fabricate in comparison with plastic or rubber (EPDM) tubing. Thus, alternative approaches to implementing a liquid-based cooling system for cooling an electronics system or subsystem are deemed desirable.

To introduce liquid coolant into a cooling system, such as a computer server unit, is necessary that the tubing and all fittings meet underwriters laboratories (UL) specifications for flammability. Metallic tubing meets these requirements, but as noted, lacks the mechanical compliance, and is expensive comparison to other options, such as ethylene propylene diene monomer (EPDM) hose. Unfortunately, EPDM hose wall thicknesses are typically too large resulting in outside diameters that do not fit within the available volume of today's electronic systems, such as the systems described herein. Another option is tubing made of deformable plastic, such as polytetrafluoroethylene (PTFE), perfluoroalkoxy (PFA), fluorinated ethylene-propylene (FEP), or other polymer tubing. These tubings meet UL specification requirements, but are difficult to seal to a fitting. Conventionally, such plastic tubing would be attached to a fitting via a compression adapter or clamp which seals to the outside of the tubing. This is also unacceptable in the implementations described herein due to the limited volume available. The compression adapter's available today produce an excessive connection volume when used in parallel in embodiments with multiple such connections.

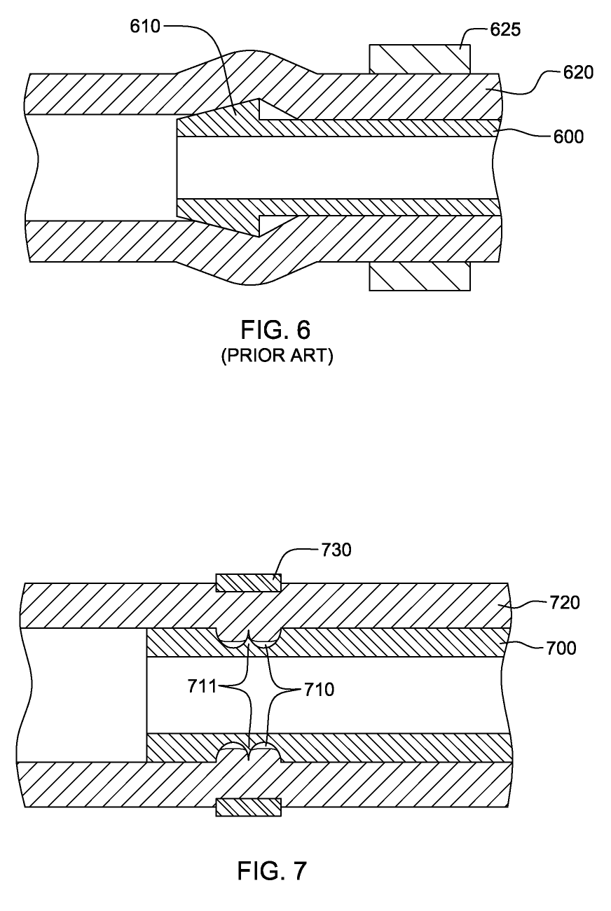

Another approach is depicted in FIG. 6, wherein an external barb fitting is employed. As shown in FIG. 6, a fitting 600 is sized to reside within a flexible hose 620, which deforms about an exterior barb 610 in fitting 600 with placement of the fitting into the hose. Note that the barb's diameter is larger than the hose 620 inner diameter requiring the hose to deform concentrically outward. This works well for very compliant rubber and similar materials (but the above-described plastic tubing and other polymers are less compliant and do not easily deform over barbs). A compression clamp 625 is also typically provided and involves other hardware in the form of a tab to be deformed to create the clamping force or an actuation mechanism (e.g., a worm gear and slots in the clamp body), further increasing the required volume for the assembly. As noted, an external barb fitting such as illustrated in FIG. 6 would be unworkable with plastic tubing, such as the above-described PTFE, PFA, FEP or other polymer tubing, which is typically firmer than a rubber hose, and therefore does not conform to the intended shape, even if a traditional hose clamp is applied.

One embodiment of an alternative approach to forming a mechanical, fluid-tight connection using such tubing is depicted in FIG. 7. In this figure, a grooved fitting 700 (fabricated, for example, of metal) is provided having an outer diameter sized to slip or friction fit within the inner diameter of a tubing 720. As illustrated, fitting 700 is a grooved fitting having one or more circumferential grooves 710 disposed about an outer surface of the fitting within the region of overlap between the fitting and tubing. Formed within each circumferential groove 710 are one or more raised features 711, such as barbs, which server to grip and seal tubing 720 to fitting 700 when the tubing is deformed into the circumferential groove, for example, via a shape memory alloy ring (or clamp).

Advantageously, the apparatus of FIG. 7 is easily assembled by placing the relatively stiff, but plastically deformable, tubing over the grooved fitting, and positioning shape memory alloy (SMA) ring 730 over the tubing 720, aligned at least partially over circumferential groove 710 in the grooved fitting 700. Heat shrinking of SMA ring 730 provides the necessary permanent clamping force to plastically deformed tubing 720 into circumferential groove 710, and into contact with raised feature(s) 711 within the circumferential groove, and to maintain the tube on the barb thereby creating the mechanical, fluid-tight seal. This approach to creating the connection is superior to the above-described solutions in view of its small size, and ease of assembly. The tubing should be selected so as to be able to deform into the circumferential groove when heat-shrunk clamped, as described herein. Note that one or more raised features may be provided within the circumferential groove, and that multiple circumferential grooves may also be provided, if desired (e.g., with the use of multiple SMA rings). Each raised feature comprises, in one example, a barb, which may be a continuous circumferential barb within the circumferential groove. As illustrated, the barb does not extend beyond the outer surface of the groove fitting, which facilitates slip fitting of the grooved fitting into the tubing.

In one embodiment, the grooved fitting may be fabricated of a metal, such as stainless steel, copper or aluminum, while the SMA ring (or clamp) may be any commercially available SMA clamp, such as the heat shrinkable rings offered by Intrinsic Devices, Inc. of San Francisco, Calif. In one implementation, rectangular cross-section SMA clamps may be chosen for use in an apparatus as presented herein. The depth of the circumferential groove, and the heat shrink characteristics of the SMA clamp may be chosen by one skilled in the art for a particular implementation based upon the description provided herein.

Heat shrinkage of the SMA clamps can be via a conventional oven or a belt oven, with oven temperatures set between 165° C. and 200° C. The higher temperature will give a more rapid heating if acceptable with the surrounding structures. Further, use of a convection oven may reduce heating times. SMA rings (or clamps) will begin to shrink at over 45° C. and be almost fully shrunk by 100° C., however, they require heating to 165° C. to build their full clamping force. A controlled heating method is employed to ensure that the SMA ring reaches the desired temperature. If desired, rings with a paint spot can be obtained which change color once the ring has obtained a 165° C. temperature. A nominal radial clamping force for a designed purpose is equal to the ring to substrate contact area×the contact pressure. The actual force applied by an SMA ring after heat shrinking is a function of the installation method, substrate material and geometry, and operating temperatures. The force decreases with decreasing applied temperature and with decreasing substrate diameter. Testing may be required to qualify performance for a specific mechanical, fluid-tight connection application.

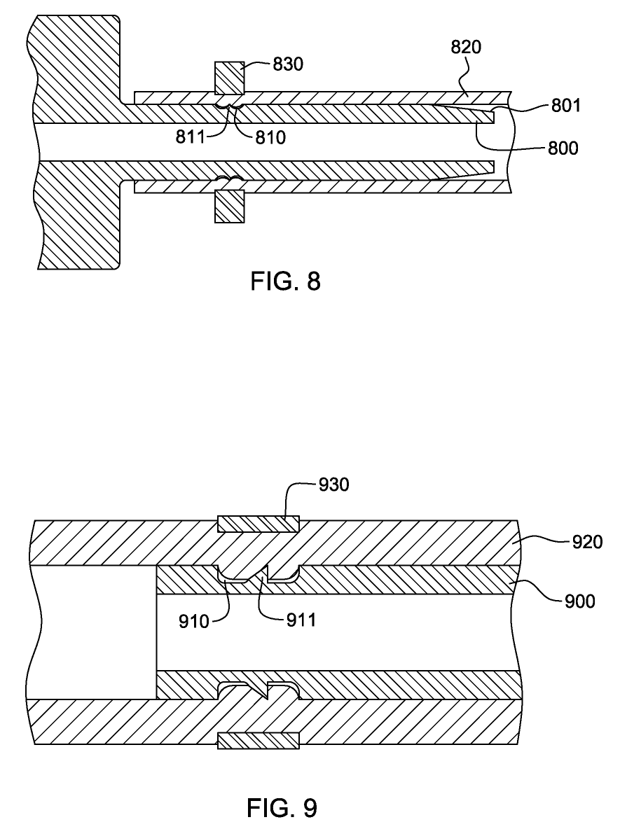

FIG. 8 depicts a more detailed implementation of a mechanical, fluid-tight connection using the apparatus of FIG. 7. In this embodiment, grooved fitting 800 includes a tapered distal end 801, which facilitates insertion of the fitting into deformable tubing 820 (fabricated, for example, of the above-described PTFE, PFA, FEP, or other polymer material). A circumferential groove 810 is formed within grooved fitting 800 and one or more raised features 811 are provided within the groove, which continuously extend circumferentially within the groove. An SMA ring 830 is positioned in alignment over circumferential groove 810 and shown after heat shrinking to plastically deform a portion of tubing 820 into circumferential groove 810 and into contact with the raised feature(s) 811. As noted above, the cross-sectional configuration of SMA ring 830 may vary. In one embodiment, the width Wᵣ of SMA ring 830 is less than or equal to the width W_{g} of circumferential groove 810 over which the ring is aligned. This facilitates deformation of the tubing into the circumferential groove with heat shrinking of the SMA ring.

As illustrated in FIGS. 7 & 8, an axially-facing surface (or inner surface) of the ring has an inner diameter which shrinks with heating of the SMA ring. Shrinkage of this inner diameter results in force being applied to plastically deform tubing 820, forcing a portion of the tubing into the circumferential grove 810, and into contact with the raised feature(s) within the groove. The SMA ring is created to a final (actuated) dimension, then mechanically stretched to a larger opening diameter which will readily slide over the tubing's outer diameter. After the SMA ring is placed in position over the tubing, aligned over at least a portion of the circumferential groove in the grooved fitting, the assembly is heated to both soften the tubing and to entice the SMA ring to return to its original shape, which is a well known property of an SMA material. The resulting connection configuration is illustrated in FIGS. 7 & 8. Advantageously, the illustrated mechanical, fluid-tight connection can be employed within a cooling system such as described above. The connection requires minimum additional volume, and allows for the use of a PTFE, PFA, FEP or other polymer tubing, which is more flexible than the above-described metal tubing of the example of FIG. 5.

FIGS. 9 & 10 depict embodiments of an alternate apparatus wherein the raised feature is an asymmetrical barb, in contrast to the symmetrical barb of FIGS. 7 & 8. Specifically, referring to FIG. 9, a grooved fitting 900 is provided with an outer diameter sized to slide or friction fit within the inner diameter of a tubing 920. Grooved fitting 900 includes a circumferential groove 910 disposed near an end thereof, within the tubing. In this configuration, an asymmetrical barb 911 is provided, and may comprise, for example, a continuous barb extending circumferentially within the circumferential groove 910 of grooved fitting 900. The asymmetrical barb 911 preferably does not extend beyond the outer diameter of the grooved fitting, so as not to interfere with the fitting being inserted into the tubing. An SMA ring 930 such as described above is shown positioned over tubing 920 and over circumferential groove 910. As illustrated, heat shrinking has occurred and SMA clamp 930 has forced a portion of deformable tubing 920 into the circumferential groove and into biting engagement with the asymmetrical barb 911, thereby forming the mechanical, fluid-tight connection.

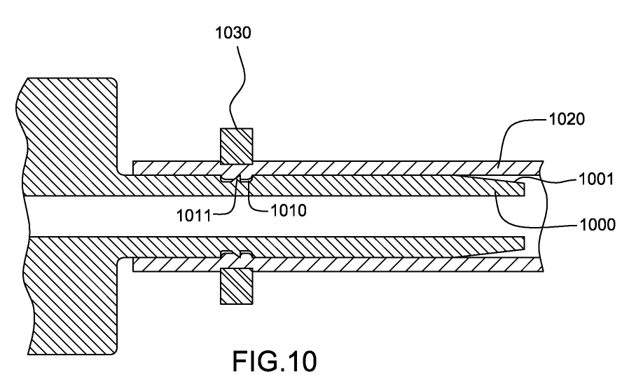

FIG. 10 illustrates a more detailed implementation of this embodiment, wherein a grooved fitting 1000 has a tapered distal end 1001 to facilitate insertion of tubing 1020 over the fitting. The grooved fitting 1000 includes a circumferential groove 1010 in a projection portion thereof shown disposed within tubing 1020. An asymmetrical barb 1011, such as illustrated in FIG. 9, resides within the circumferential groove. SMA ring 1030 is shown positioned over the tubing 1020, in alignment of the circumferential groove 1010, with heat shrinking of the SMA ring having resulted in plastic deformation of tubing 1020 into the circumferential groove 1010, and into biting engagement with asymmetrical barb 1011.

Various prototypes of the apparatus described above have been tested. In one embodiment, the fitting and barb designs of FIGS. 7-10 were built of stainless steel and assembled into an FEP tubing using SMA clamps. Both barb designs were tested for leakage by pressurizing the tube connection to 50 psig (hydrostatic) with air in a water bath. Both designs held pressure without any visible leakage. Further testing was done to demonstrate the burst pressure and assemblies using water and a hand pump. The designs shown in FIGS. 7-10 experienced tube failure at approximately 600 psig.

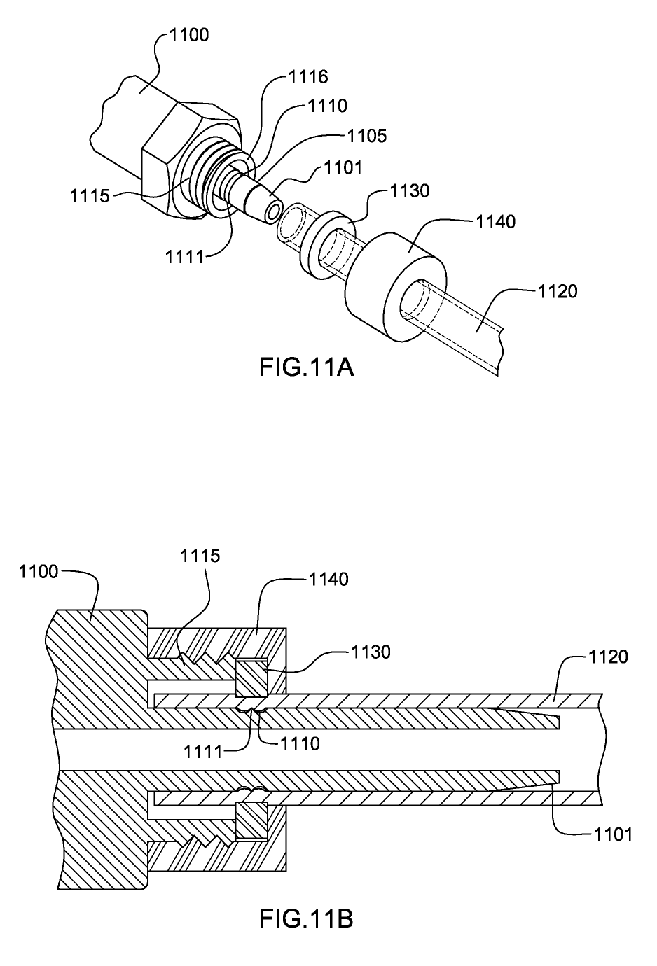

FIGS. 11A-11B depict a further embodiment of an apparatus in accordance with an aspect of the present invention. This apparatus builds upon the connection embodiment of FIGS. 7 & 8 by way of example only. Other raised feature embodiments may be employed with an apparatus such as depicted in FIGS. 11A & 11B.

As illustrated, a fitting 1100 is provided which includes a fitting projection 1105 having a tapered end 1101 to facilitate insertion of the fitting projection into a tubing 1120 such as the above-described PTFE, PFA, FEP or other polymer tubing. The fitting projection 1105 is provided with one or more circumferential grooves 1110 having one or more raised features 1111 disposed within the groove, such as described above in connection with the embodiments of FIGS. 7-10. In this embodiment, an alignment projection 1115 is also provided extending from fitting 1100 and encircling a portion of fitting projection 1105. This alignment projection (which is cylindrical shaped in the embodiment depicted) includes a seat surface 1116 which is aligned to, for example, the proximal edge of the circumferential groove in fitting projection 1105. Seat surface 1116 is thus positioned to facilitate alignment of an SMA ring 1130 over the circumferential groove when the apparatus is assembled, as described herein.

As illustrated in FIG. 11A, the apparatus is ready for assembly with SMA ring 1130 over tubing 1120 and a threaded retaining cap 1140 also over tubing 1120. Threaded retaining cap 1140 is sized and configured to threadably engage threads on an outer surface of alignment projection 1115. The resultant assembly is illustrated in FIG. 11B wherein an inner surface of threaded retaining cap 1140 engages one side of SMA ring 1130 and the seat surface 1116, comprising the exposed end of alignment projection 1115, engages the opposite side of the SMA ring and positions the ring in the desired location over circumferential groove 1110 in fitting 1100. In FIG. 11B, SMA ring 1130 has undergone heat shrinking and a portion of tubing 1120 has deformed into the circumferential groove 1110 and into contact with raised feature 1111. Advantageously, the seat surface facilitates proper positioning of the SMA ring over the circumferential groove in the fitting, and the threaded retaining cap (when threadably engaged to the alignment projection) serves to provide additional mechanical rigidity to the mechanical, fluid-tight connection formed by the apparatus, both before and after heat shrinking of the SMA ring to plastically deform the tubing into the circumferential groove and into contact with the one or more raised features within the groove.

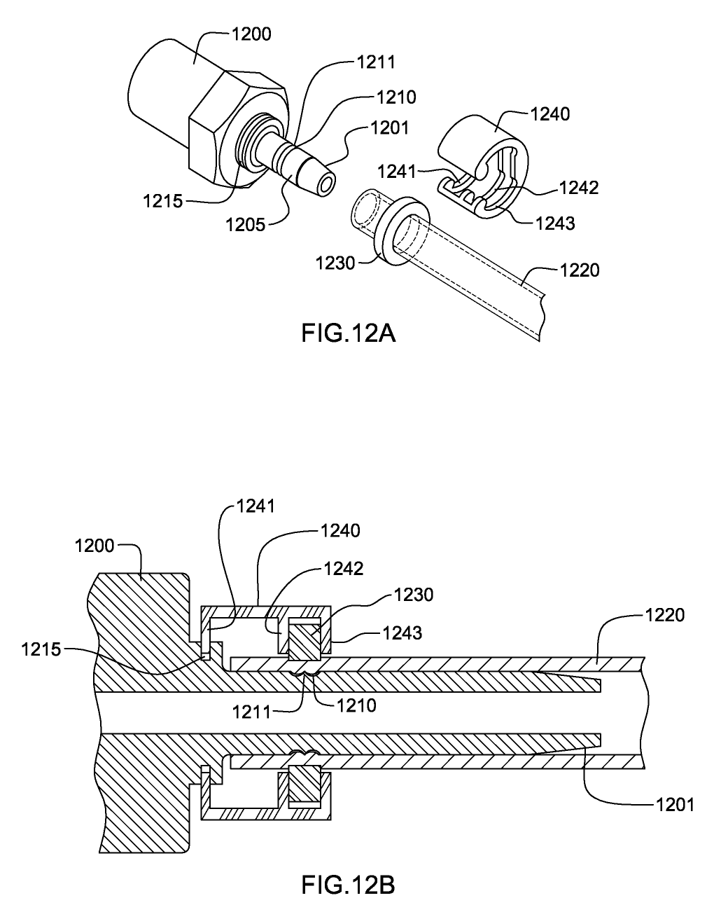

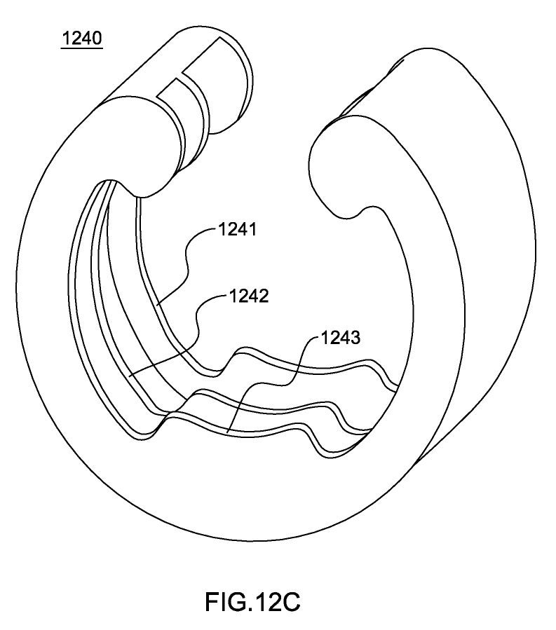

FIGS. 12A-12C depict a further embodiment of an apparatus in accordance with a present invention. Although built upon the configuration of FIGS. 7 & 8, the apparatus could employ a raised feature within the circumferential groove of any desired design, provided the raised feature is sufficient to bite into, and thereby hold the tubing when plastically deformed into the circumferential groove with heat shrinking of the SMA ring.

As shown in FIGS. 12A & 12B, the apparatus includes a fitting 1200 having a fitting projection 1205 with a tapered distal end 1201 to facilitate insertion of the fitting projection into a tubing 1220 such as the above-described PTFE, PFA, FEP or other polymer tubing. A circumferential groove 1210 is provided within fitting projection 1205 such as described above and includes a raised feature 1211 configured, for example, as the symmetrical barb in the embodiment of FIGS. 7 & 8. Other raised feature configurations could also be employed, however. The SMA ring 1230 is shown in FIG. 12A positioned over tubing 1220, and also shown is a retaining clip 1240. A retaining slot 1215 is provided within a portion of fitting 1200 to be engaged by a first arm 1241 of retaining clip 1240. FIG. 12C illustrates that retaining clip 1240 includes, in addition to first arm 1241, a second arm 1242 and a third arm 1243. Second and third arms 1242, 1243, are disposed in opposing relation and spaced apart a distance sufficient to accommodate the SMA ring 1230 (see FIG. 12B) therebetween. As illustrated in FIG. 12B, first arm 1241 when in operative position engages retaining slot 1215 of fitting 1200 and the retaining clip is sized such that SMA ring 1230, held between second arm 1242 and third arm 1243, is positioned in alignment over the circumferential groove 1210 in fitting 1200. As illustrated in FIG. 12C, the projections of first, second and third arms may vary. Further, the opening in the C-shaped retaining clip example depicted in FIGS. 12A-12C is sufficient to allow the retaining clip to be readily slipped over the outer diameter of tubing 1220.

To assemble the apparatus depicted in FIGS. 12A-12C, the unactuated SMA ring is placed over the tubing, and the tubing and SMA ring assembly is pushed onto the fitting projection 1205, with the SMA ring roughly positioned in alignment over the circumferential groove in the fitting projection. The retaining clip is then placed over the assembly with the SMA ring held between the second and third arms and with the first arm held within the retaining slot of the fitting. Thus, with the proper sizing and configuration of the retaining clip, it can be assured that the SMA ring is positioned in alignment over the circumferential groove in the fitting projection. Temperature of the resultant assembly is then raised to heat shrink the SMA ring into position, plastically deforming the tubing resulting in the tubing coming into contact with the raised feature within the circumferential groove and forming the mechanical, fluid-tight seal. The retaining clip facilitates the assembly process by ensuring the proper positioning of the SMA ring over the circumferential groove, and also by providing mechanical rigidity to the assembly prior to heat shrinking of the SMA ring, as well as additional mechanical strength to the connection subsequent to heat shrinking.

Although preferred embodiments have been depicted and described in detail herein, it will be apparent to those skilled in the relevant art that various modifications, additions, substitutions and the like can be made without departing from the spirit of the invention and these are therefore considered to be within the scope of the invention as defined in the following claims.

What is claimed is:

1. An apparatus for forming a mechanical, fluid-tight connection, the apparatus comprising:
a grooved fitting having an outer diameter which allows at least a portion of the grooved fitting to reside within a tubing between which the mechanical, fluid-tight connection is to be formed, the grooved fitting comprising a circumferential groove about an outer surface thereof and at least one raised feature within the circumferential groove, the circumferential groove being disposed in the at least a portion of the grooved fitting to reside within the tubing;
a ring formed from a shape memory alloy, which is transversely heat-shrinkable and has an axially-facing surface, and wherein an inner diameter of the ring, at the axially-facing surface, is sized to allow the ring to reside over the tubing; and
wherein when the at least a portion of the grooved fitting resides within the tubing, and the ring resides over the tubing at least partially aligned over the circumferential groove in the outer surface of the grooved fitting, heat-shrinking of the ring results in deformation of the tubing into the circumferential groove and into contact with the at least one raised feature within the circumferential groove, thereby forming the mechanical, fluid-tight connection.

2. The apparatus of claim 1, wherein the at least one raised feature comprises at least one barb residing within the circumferential groove.

3. The apparatus of claim 1, wherein the at least one raised feature within the circumferential groove does not extend beyond the outer diameter of the grooved fitting adjacent to the circumferential groove.

4. The apparatus of claim 1, wherein the circumferential groove comprises a groove width W_{g} and wherein the ring comprises a ring width Wᵣ less than or equal to groove width W_{g}, and wherein when the ring resides over the tubing in a position aligned over the circumferential groove in the outer surface of the groove fitting, heat shrinking of the ring results in deformation of the tubing into the at least one circumferential groove and into contact with the at least one raised feature within the circumferential groove, thereby forming the mechanical, fluid-type connection.

5. The apparatus of claim 1, wherein the tubing is plastically deformable, comprising at least one of polytetrafluoroethylene (PTFE), perfluoroalkoxy (PFA), or fluorinated ethylene-propylene (FEP).

6. The apparatus of claim 1, wherein the grooved fitting comprises a fitting projection, and the at least a portion of the grooved fitting to reside within the tubing comprises at least a portion of the fitting projection, the fitting projection including the circumferential groove, and wherein the grooved fitting further comprises an alignment projection at least partially encircling the fitting projection and having a seat surface positioned such that placement of the ring against the seat surface automatically at least partially aligns the ring over the circumferential groove in the grooved fitting.

7. The apparatus of claim 6, wherein the alignment projection is cylindrical-shaped and at least partially threaded on an outer surface thereof, and wherein the apparatus further comprises a threaded retaining cap sized to threadably engage the at least partial threading on the outer surface of the alignment projection, wherein threaded engagement of the threaded retaining cap onto threads of the alignment projection increases mechanical strength of the mechanical, fluid-tight connection, and wherein the threaded retaining cap is sized such that when threaded onto the threads of the alignment projection, the ring resides between the seat surface of the alignment projection and an inner surface of the threaded retaining cap.

8. The apparatus of claim 1, further comprising a retaining clip comprising a first arm sized and configured to engageably coupled to a retaining slot in the grooved fitting for positioning the retaining clip relative to the grooved fitting, and second and third arms spaced in opposing relation and sized to retain the ring therebetween when the ring resides over the tubing at least partially aligned with the circumferential groove and the first arm is engageably coupled in the retaining slot to the grooved fitting, and wherein the retaining clip retains the ring in position until heat-shrinking of the ring results in deformation of the tubing into the at least one circumferential groove, and provides additional mechanical strength to the resultant mechanical, fluid-tight connection.

9. The apparatus of claim 8, wherein the retaining clip is C-shaped, and wherein height of at least one of the first arm, the second arm the third arm varies.

10. An assembly for facilitating cooling of an electronics system, the assembly comprising:
a deformable tubing for carrying coolant towards or away from at least one heat-generating component of the electronics system to be cooled;
a mechanical, fluid-tight connection at least one end of the deformable tubing, the mechanical, fluid-tight connection being formed between a grooved fitting of the assembly and the deformable tubing, wherein the grooved fitting has an outer diameter sized such that at least a portion of the grooved fitting resides within the deformable tubing, the grooved fitting comprising a circumferential groove about an outer surface thereof and at least one raised feature within the circumferential groove, the circumferential groove being disposed in the at least a portion of the grooved fitting residing within the deformable tubing, and the mechanical, fluid-tight connection further comprising a ring formed of shape memory alloy, which is transversely heat-shrunk and has an axially-facing surface, and wherein an inner diameter of the ring, at the axially-facing surface, was sized to allow the ring to reside over the deformable tubing prior to heat-shrinking of the ring; and
wherein heat-shrinking of the ring produced deformation of the deformable tubing into the circumferential groove and into contact with the at least one raised feature within the circumferential groove, thereby defining the mechanical, fluid-tight connection at the at least one end of the deformable tubing of the cooling assembly.

11. The assembly of claim 10, wherein the at least one raised feature comprises at least one barb residing within the circumferential groove.

12. The assembly of claim 10, wherein the at least one raised feature within the circumferential groove does not extend beyond the outer diameter of the groove fitting adjacent to the circumferential groove.

13. The assembly of claim 10, wherein the grooved fitting comprises a fitting projection, and the at least a portion of the groove fitting residing within the deformable tubing comprises at least a portion of the fitting projection, and the fitting projection includes the circumferential groove, and wherein the groove fitting further comprises an alignment projection at least partially encircling the fitting projection and having a seat surface positioned such that placement of the right against the seat surface automatically at least partially aligns the ring over the circumferential groove in the grooved fitting.

14. The assembly of claim 13, wherein the alignment projection is cylindrical-shaped and at least partially threaded at an outer surface thereof, and the assembly further comprises a threaded retaining cap sized to threadably engage the at least partial threading on the outer surface of the alignment projection, wherein threaded engagement of the threaded retaining cap onto threads of the alignment projection increases mechanical strength of the mechanical, fluid-tight connection, and wherein the threaded retaining cap is sized such that when threaded onto the threads of the alignment projection, the ring resides between the seat surface of the alignment projection and an inner surface of the threaded retaining cap.

15. The assembly of claim 10, further comprising a retaining clip comprising a first arm sized and configured to engageably couple to a retaining slot in the grooved fitting for positioning the retaining clip relative to the groove fitting, and second and third arms spaced in opposing relation and sized to retain the ring therebetween when the ring resides over the tubing at least partially aligned with the circumferential groove, and the first arm is engageably coupled in the retaining slot to the grooved fitting, and wherein the retaining clip facilitates retaining the ring in position until heat shrinking of the ring results in deformation of the deformable tubing into the at least one circumferential groove and provides additional mechanical strength to the resultant mechanical, fluid-tight connection.

16. A method of forming a mechanical, fluid-tight connection, the method comprising:
obtaining a grooved fitting having an outer diameter sized to allow at least a portion of the grooved fitting to reside within a tubing between which the mechanical, fluid-tight connection is to be formed, the grooved fitting comprising a circumferential groove about an outer surface thereof and at least one raised feature within the circumferential groove, the circumferential groove being disposed in the at least a portion of the grooved fitting sized to reside within the tubing;
obtaining a ring formed from a shape memory alloy, which is transversely heat-shrinkable and has an axially-facing surface, and wherein an inner diameter of the ring, at the axially-facing surface, is sized to allow the ring to reside over the tubing;
placing the at least a portion of the grooved fitting within the tubing and positioning the ring over the tubing at least partially in alignment over the circumferential groove in the outer surface of the grooved fitting; and
heat-shrinking the ring to deform the tubing into the at least one circumferential groove in the grooved fitting and into contact with the at least one raised feature within the circumferential groove, thereby forming the mechanical, fluid-tight connection.

17. The method of claim 16, wherein the at least one raised feature comprises at least one barb residing within the circumferential groove and not extending beyond the outer diameter of the grooved fitting adjacent to the circumferential groove, and wherein the tubing is plastically deformable, comprising at least in part one of polytetrafluoroethylene (PTFE), perfluoroalkoxy (PFA), or fluorinated ethylene-propylene (FEP).

18. The method of claim 16, wherein the grooved fitting comprises a fitting projection, and the at least a portion of the grooved fitting to reside within the tubing comprises at least a portion of the fitting projection, the fitting projection including the circumferential groove, and wherein the grooved fitting further comprises an alignment projection at least partially encircling the fitting projection and having a seat surface positioned such that placement of the ring against the seat surface automatically at least partially aligns the ring over the circumferential groove in the grooved fitting.

19. The method of claim 18, wherein the alignment projection is cylindrical shaped and at least partially threaded on an outer surface thereof, and wherein the method further comprises obtaining a threaded retaining cap sized to threadably engage the at least partial threading on the outer surface of the alignment projection, wherein threaded engagement of the threaded retaining cap onto threads of the alignment projection increases mechanical strength of the mechanical, fluid-tight connection, and wherein the threaded retaining cap is sized such that when threaded onto the threads of the alignment projection, the ring resides between the seat surface of the alignment projection and an inner surface of the threaded retaining cap.

20. The method of claim 16, further comprising a retaining clip comprising a first arm sized and configured to engageably coupled to a retaining slot in the grooved fitting for positioning the retaining clip relative to the grooved fitting, and second and third arms spaced in opposing relation and sized to retain the ring therebetween when the ring resides over the tubing at least partially aligned with the circumferential groove, and the first arm is engageably coupled in the retaining slot to the grooved fitting, and wherein the retaining clip retains the ring in position until heat-shrinking of the ring results in deformation of the tubing into the at least one circumferential groove, and provides additional mechanical strength to the resultant mechanical, fluid-tight connection.
